(19) United States
(12) Patent Application Publication
(10) Pub. No.: US 2007/0029068 A1
(43) Pub. Date: Feb. 8, 2007

(54) Heat sink

(76) Inventors: Ming-Jen Cheng, Sanchong City (TW); Yuh-Chieh Chu, Keelung (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/195,632

(22) Filed: Aug. 3, 2005

(51) Int. Cl. H05K 7/20

(52) U.S. Cl. 165/80.3; 165/185; 361/704

(57) ABSTRACT

A heat sink has a base and multiple fins. The fins are attached to the base, and each fin has a radiating surface and a conducting surface. The conducting surface is formed on the radiating surface and has at least one side abutting the base. The base is attached to an integrated circuit to dissipate heat from the integrated circuit. Because at least one of the two sides of the conducting surfaces is in full contact with the base, more heat is conducted from the base to the fins. Therefore the heat sink can cool the integrated circuit effectively.

### BACKGROUND OF THE INVENTION

1. Field of the Invention

The present invention relates to a heat sink, especially to a heat sink that is attached to an integrated circuit to effectively cool the integrated circuit.

2. Description of the Prior Arts

When integrated circuits operate, the integrated circuits generate heat, and the temperatures of the integrated circuits rise. High temperature decreases the working efficiency of integrated circuits and makes integrated circuit break easily. Therefore, heat sinks are usually attached to integrated circuits to dissipate heat generated by the integrated circuit.

With reference to FIGS. 14 and 15, a conventional heat sink comprises a base (80) and multiple fins (90). The base (80) has multiple mounting slots (81). The mounting slots (81) are formed in the base (80), and each slot (81) has two open edges. The fins (90) are mounted respectively in the mounting slots (81). A die (30) moves downward between the fins (90), presses and deforms the base (80) between the slots (81) and securely crimps the fins (90) between the deformed open edges of the mounting slots (81). Therefore the fins (90) are mounted securely in the mounting slots (81).

The base (80) is attached to the integrated circuit to dissipate heat from the integrated circuit. The fins (90) radiate the heat conducted by the base (80) to the ambient air to cool the integrated circuit. The heat conducting efficiency between the base (80) and the fins (90) is better when the contact surface is large. However, the fins (90) only contact the base (80) at the bottom and the crimped open edges of the mounting slots (81) so the base (80) cannot conduct heat to the fins (90) optimally. Therefore the conventional heat sink cannot cool the integrated circuit effectively.

To overcome the shortcomings, the present invention provides an improved heat sink to mitigate or obviate the aforementioned problems.

### SUMMARY OF THE INVENTION

The main objective of the present invention is to provide a heat sink that has better heat conducting efficiency. The heat sink has a base and multiple fins. The fins are attached to the base, and each fin has a radiating surface and a conducting surface. The conducting surface is formed on the radiating surface and has at least one side abutting the base. The base is attached to an integrated circuit to dissipate heat from the integrated circuit. Because at least one of the two sides of the conducting surfaces is in full contact with the base, more heat is conducted from the base to the fins. Therefore the heat sink can cool the integrated circuit effectively.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a first embodiment of a heat sink in accordance with the present invention;

FIG. 2 is a perspective view of the heat sink in FIG. 1;

FIG. 3 is an operational side view in partial section of the heat sink in FIG. 1;

FIG. 4 is a cross sectional side view of the heat sink in FIG. 1;

FIG. 5 is a cross sectional front view of the heat sink in FIG. 1;

FIG. 6 is an exploded perspective view of a second embodiment of a heat sink in accordance with the present invention;

FIG. 7 is a perspective view of the heat sink in FIG. 6;

FIG. 8 is an operational side view in partial section of the heat sink in FIG. 6;

FIG. 9 is a cross sectional front view of the heat sink in FIG. 6;

FIG. 10 is an exploded perspective view of a third embodiment of a heat sink in accordance with the present invention;

FIG. 11 is a perspective view of the heat sink in FIG. 10;

FIG. 12 is an operational side view in partial section of the heat sink in FIG. 10;

FIG. 13 is a side view in partial section of the heat sink in FIG. 10;

FIG. 14 is an operational side view in partial section of a conventional heat sink in accordance with the prior art; and

FIG. 15 is a side view in partial section of the conventional heat sink in FIG. 14.

### DETAILED DESCRIPTION OF THE PREFERRED EMBODIMENTS

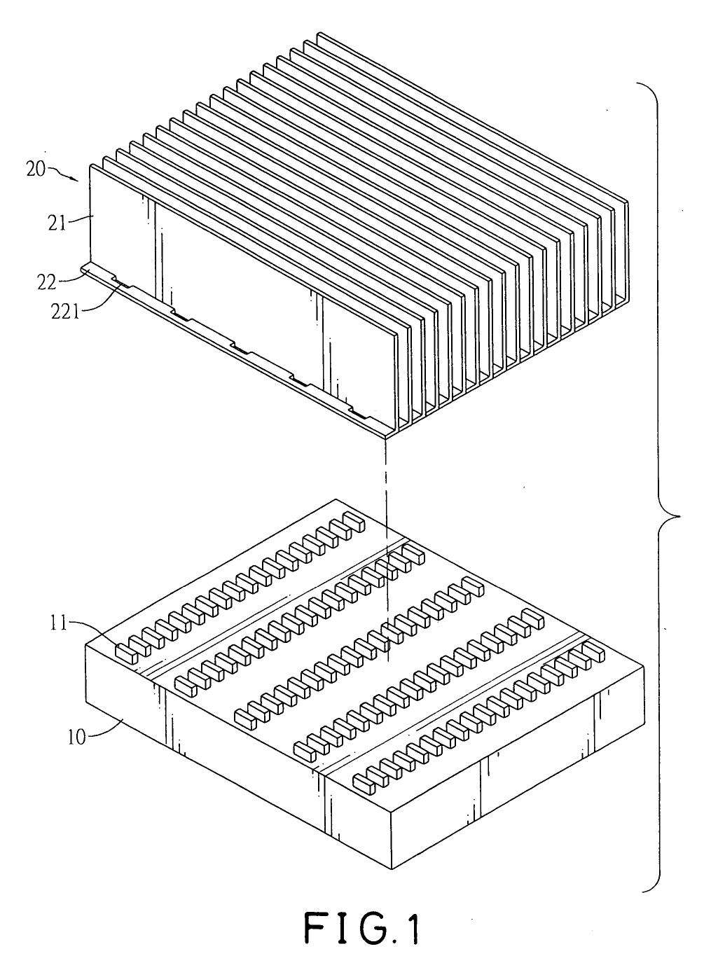

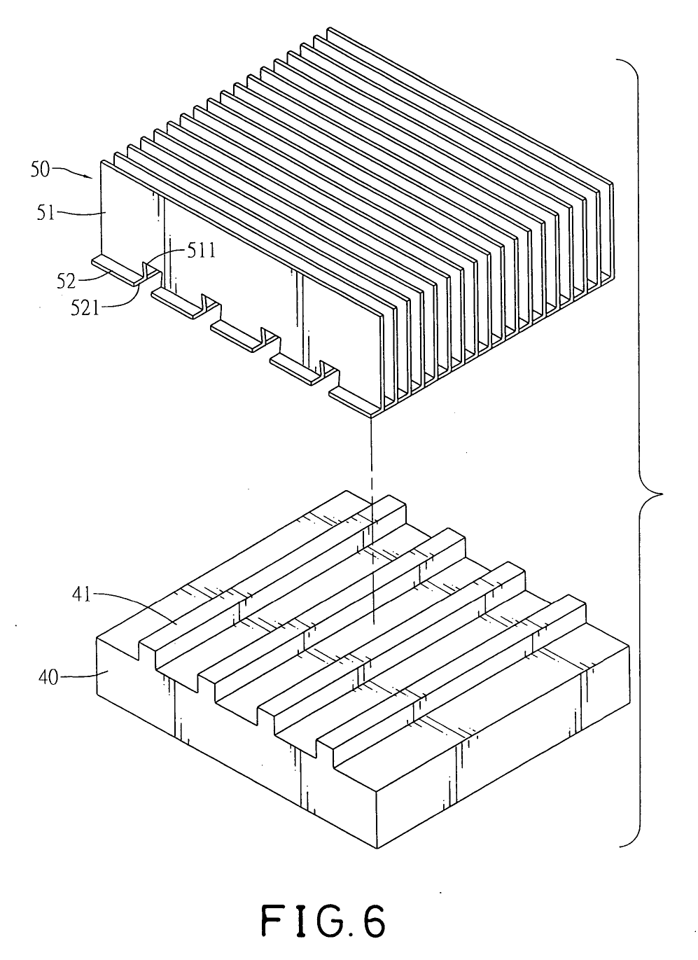

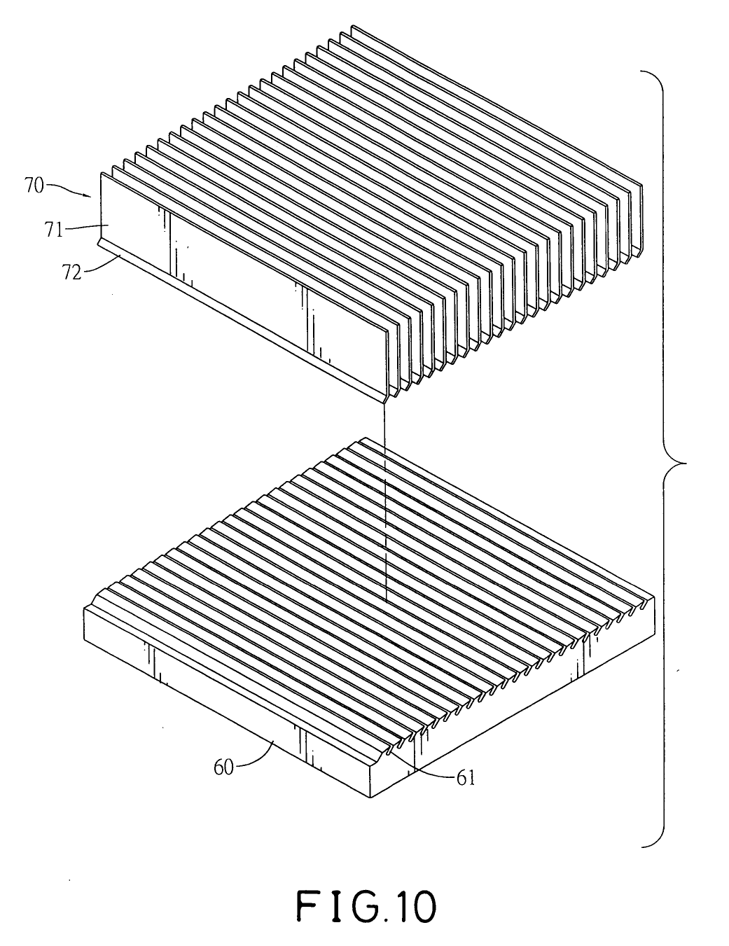

With reference to FIGS. 1, 6 and 10, a heat sink in accordance with the present invention comprises a base (10, 40, 60) and multiple fins (20, 50, 70).

The base (10, 40, 60) may have multiple protrusions (11), multiple ribs (41) or multiple inclined slots (61). The protrusions (11) are formed separately on the base (10) and may be parallel to each other, and each protrusion (11) has an enlarged distal end. The ribs (41) are formed separately on the base (40) and may be parallel to each other, and each rib (41) has an enlarged distal end. The inclined slots (61) are formed separately in the base (60) and may be parallel to each other and at an inclined angle.

The fins (20, 50, 70) are attached to the base (10, 40, 60), and each fin (20, 50, 70) has a radiating surface (21, 51, 71) and a conducting surface (22, 52, 72).

Each radiating surface (21, 51, 71) has a distal end and a proximal end and may have multiple notches (511). The notches (511) are formed separately in the proximal end of the radiating surface (51).

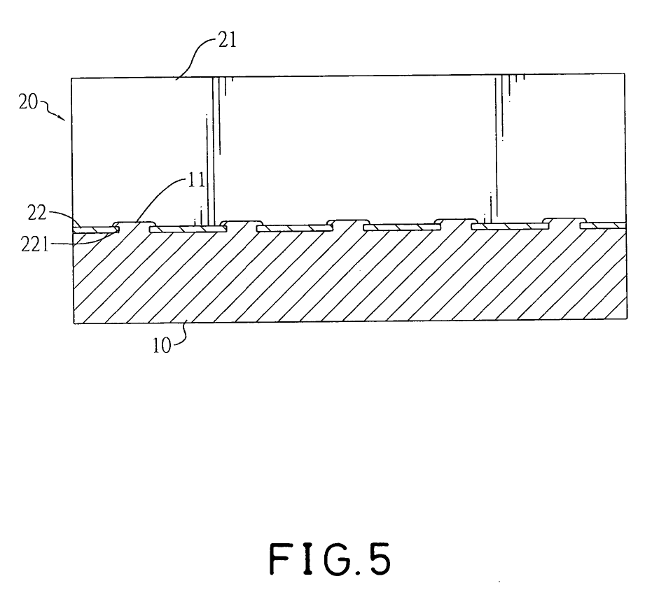

With further reference to FIGS. 4, 5, 9 and 13, the conducting surface (22, 52, 72) is formed on the proximal end of the radiating surface (21, 51, 71), may be perpendicular to the radiating surface (21, 51) or at an inclined angle relative to the radiating surface (71), has two sides and may have multiple through holes (221) or multiple notches (521). At least one of the two sides of the conducting surface (22, 52, 72) completely contacts with the base (10, 40, 60).

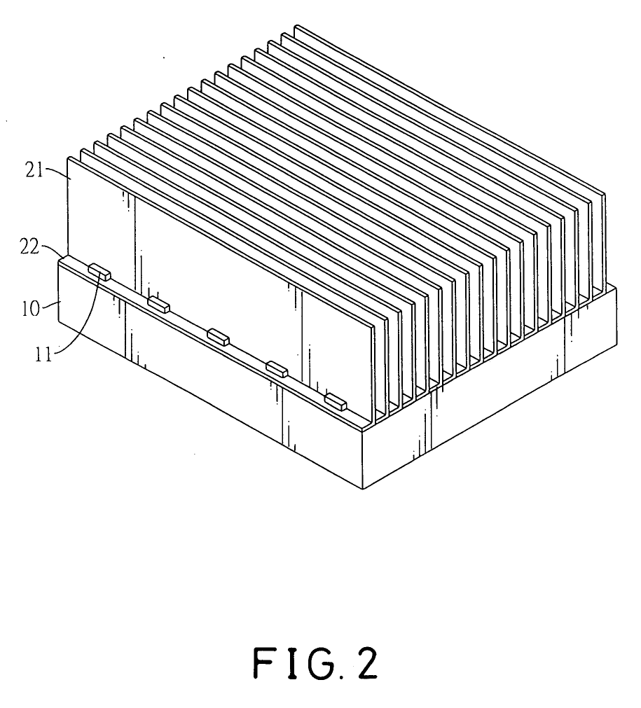

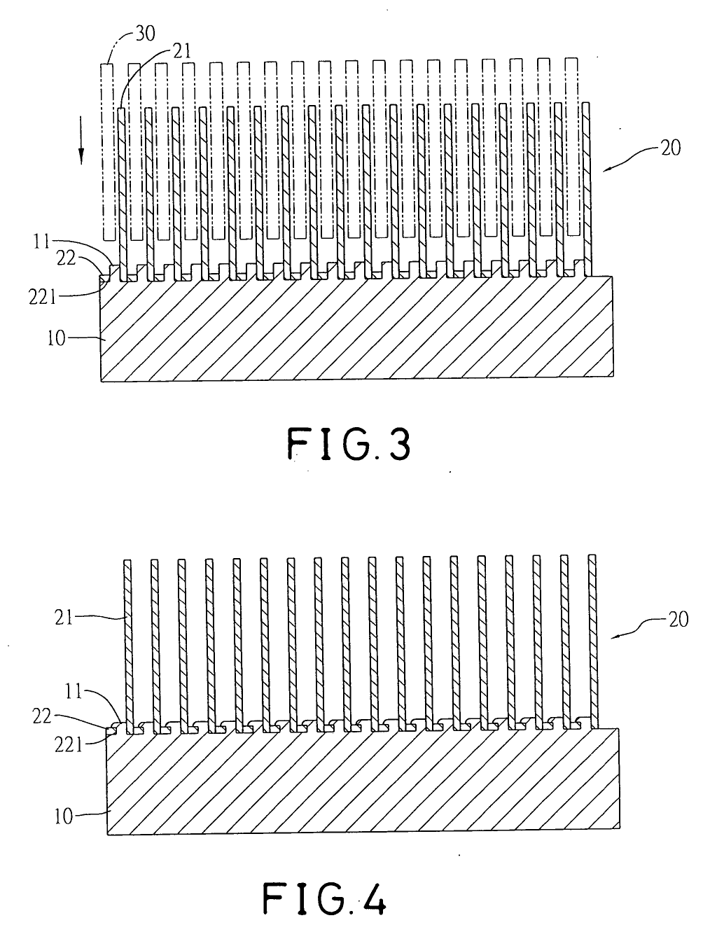

The through holes (221) are formed separately in the conducting surface (22) and are mounted respectively around the protrusions (11) on the base (10). With further reference to FIGS. 2 and 3, the enlarged distal ends of the protrusions (11) are flattened and expanded with a die (30) to press against one side of the conducting surfaces (22) and hold the fins (21) securely on the base (10).

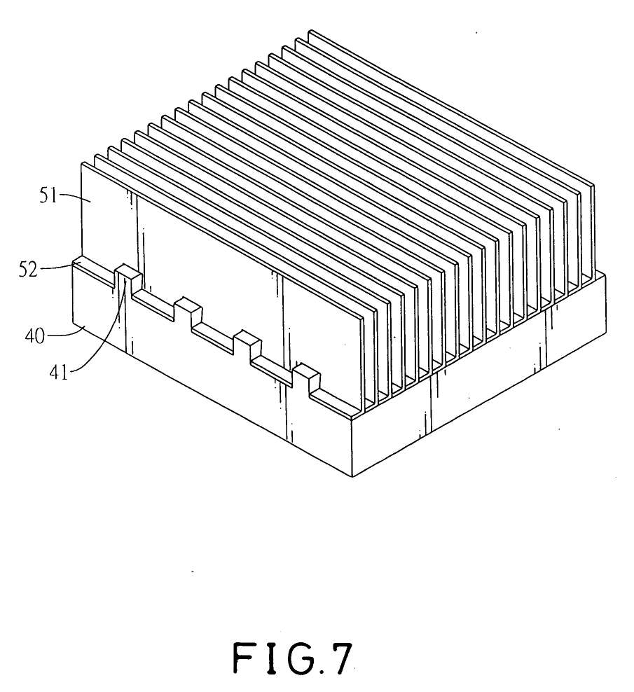

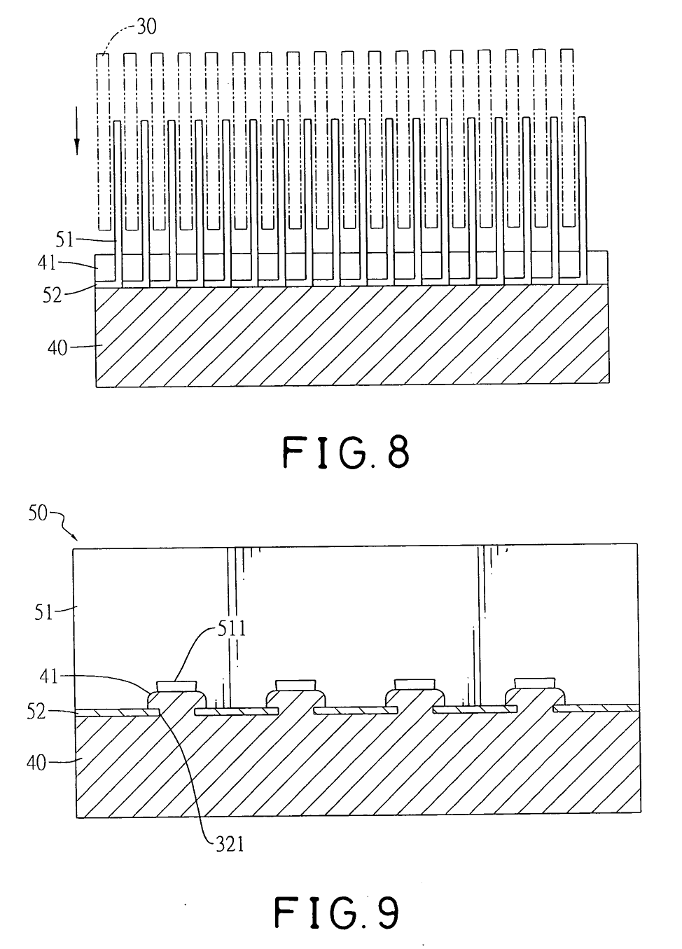

The notches (521) are formed separately in the conducting surface (52), correspond to and communicate respectively with the notches (511) in the radiating surface (51) and are mounted respectively around the ribs (41) on the base (40). With further reference to FIGS. 7 and 8, the enlarged distal ends of the ribs (41) between the between the radiating surfaces (51) are flattened and expanded with a die (30) to press against one side of the conducting surfaces (52) and hold the fins (51) securely on the base (40).

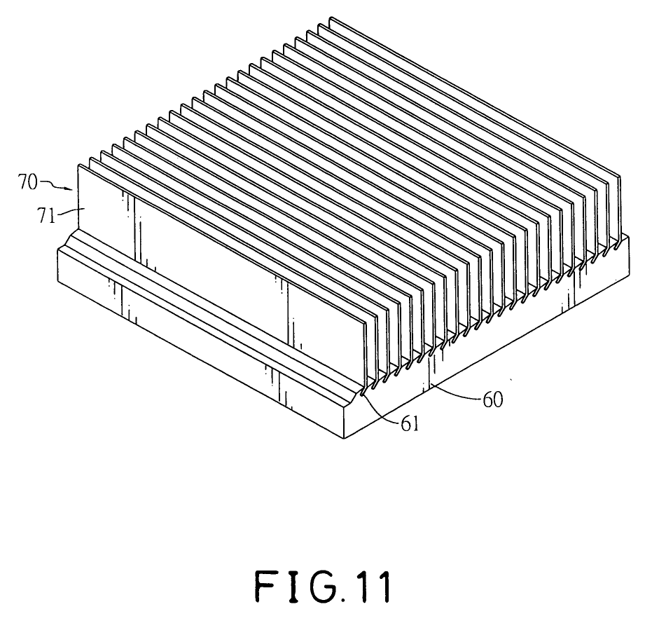

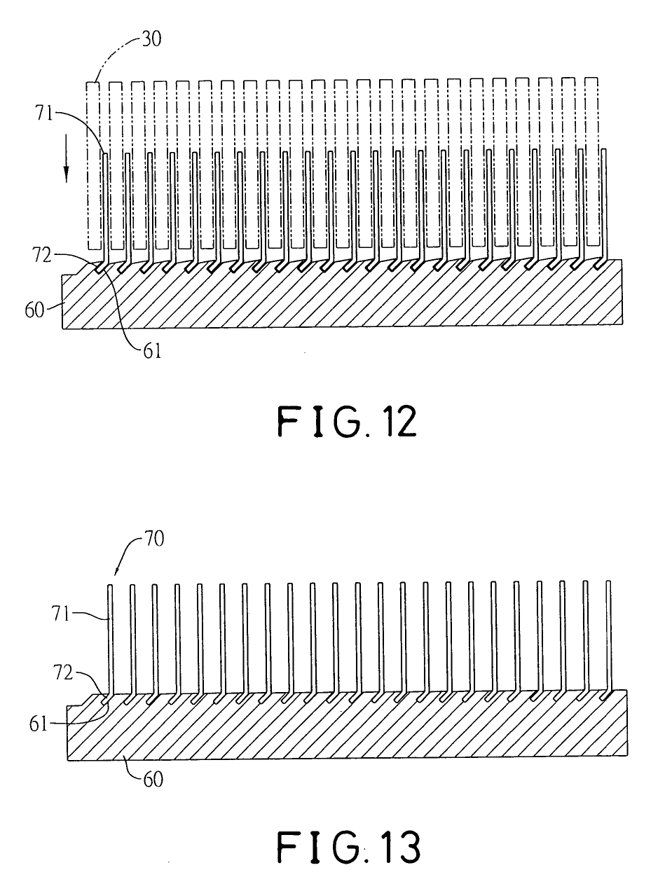

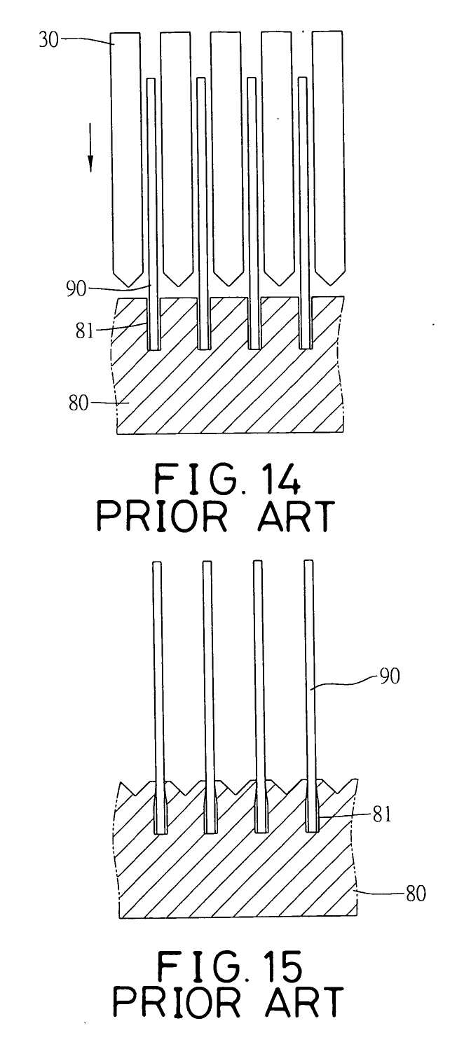

The inclined angle between the conducting surface (72) and the radiating surface (71) corresponds to the inclined angle of the inclined slots (61) in the base (60) and is between 90-180 degrees. In the preferred embodiment, the inclined angle between the conducting surface (72) to the radiating surface (71) is 135 degrees. With further reference to FIGS. 11 and 12, the conducting surfaces (72) are mounted respectively in the inclined slots (61) in the base (60). The base (60) is deformed and expanded with a die (30) to compress the inclined slots (61) against and clamp the two sides of the conducting surfaces (72) to hold the fins (71) securely on the base (60).

The base (10, 40, 60) is attached to an integrated circuit to dissipate heat from the integrated circuit. Because at least one of the two sides of the conducting surfaces (22, 52, 72) is in full contact with the base (10, 40, 60), more heat is conducted from the base (10, 40, 60) to the fins (20, 50, 70). Therefore the heat conducting efficiency of the heat sink is better, and the heat sink as described can cool the integrated circuit effectively.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A heat sink comprising
a base; and
multiple fins attached to the base, and each fin having
a radiating surface having a distal end and a proximal end; and
a conducting surface formed on the proximal end of the radiating surface and having two sides wherein at least one of the two sides completely contacts with the base.

2. The heat sink as claimed in claim 1, wherein
the base has multiple protrusions formed separately on the base, and each protrusion has an enlarged distal end;
each conducting surface of the fins is perpendicular to the radiating surface and has multiple through holes formed separately in the conducting surface and mounted respectively around the protrusions on the base; and
the enlarged distal ends of the protrusions abut the conducting surface to hold the fins securely on the base.

3. The heat sink as claimed in claim 2, wherein the protrusions are parallel to each other.

4. The heat sink as claimed in claim 1, wherein
the base has multiple ribs formed separately on the base, and each rib has an enlarged distal end;
each radiating surface of the fins has multiple notches formed separately in the proximal end of the radiating surface; and
each conducting surface of the fins has multiple notches formed separately in the conducting surface, corresponding to and communicating respectively with the notches in the radiating surface and mounted respectively around the ribs on the base;
the enlarged distal ends of the ribs between the radiating surfaces abut the conducting surfaces to hold the fins securely on the base.

5. The heat sink as claimed in claim 4, wherein the ribs are parallel to each other.

6. The heat sink as claimed in claim 1, wherein
the base has multiple inclined slots formed separately in the base at an inclined angle;
the conducing surfaces of the fins are mounted respectively in the inclined slots in the base, and each conducting surface is formed at an inclined angle relative to the radiating surface corresponding to the inclined angle of the inclined slots in the base and being between 90-180 degrees wherein the inclined slots clamp the two sides of the conducting surfaces to hold the fins securely on the base.

7. The heat sink as claimed in claim 6, wherein the inclined angle of the conducting surface is 135 degrees.
